(19) United States
(12) Patent Application Publication
(10) Pub. No.: US 2004/0207010 A1
(43) Pub. Date: Oct. 21, 2004

(54) Semiconductor device and method of manufacturing the same

(76) Inventor: Tomoyuki Furuhata, Sakata-shi (JP)

Correspondence Address: EDWARDS & ANGELL, LLP, P.O. BOX 55874, BOSTON, MA, 02205, US

(21) Appl. No.: 10/799,144

(22) Filed: Mar. 11, 2004

(30) Foreign Application Priority Data
Mar. 14, 2003 (JP) 2003-070549

(51) Int. Cl. H01L 29/76; H01L 21/336

(52) U.S. Cl. 257/335; 438/306; 257/336; 257/344

(57) ABSTRACT

A semiconductor device is a P-channel type MOS field effect transistor that comprises; a semiconductor substrate, a gate oxide film positioned on the semiconductor substrate, a gate electrode positioned on the gate oxide film; and two P+ source and drain diffusion areas, each of which has a P− offset area, that are formed in an n-well region of the semiconductor substrate. At least one of the gate electrode, the gate oxide film and the offset areas contains fluorine.

Japanese Patent Application 2003-070549 filed on Mar. 14, 2003 is hereby incorporated by reference in its entirety.

### BACKGROUND

1. Field of the Invention

The present invention relates to a semiconductor device and a manufacturing method of the semiconductor device, and especially relates to a semiconductor device, which includes a P-channel type MOS field effect transistor, and a manufacturing method of the semiconductor device.

2. Description of the Related Art

To meet requirements of lower power consumption and lower voltage for electronic equipment in recent years, P-channel type MOS field effect transistors (hereinafter called PMOSFET) have been used for various electronic appliances. Various types of densely-integrated PMOSFET structures are proposed (for example, refer to Japanese Patent Laid-Open Publication No. 1996-255903). The reason is that, in operation of a PMOSFET semiconductor device, the threshold voltage for turning on the field effect transistor can be lower than that for a N-channel type MOS field effect transistor so that lower power consumption for the semiconductor device can be materialized. Particularly, for electronic appliances using a battery for their power supply, greater power consumption in stand-by condition results in frequent re-charging of the battery. Therefore, PMOSFET semiconductor devices are widely used for those electronic appliances. Furthermore in the future it is expected that PMOSFET's will be used to further reduce the size and power requirements of semiconductor devices.

However, in regular operation at a constant temperature of a PMOSFET formed with micro patterns (for example, 0.2 μm or less) under a condition where negative voltage is applied to the gate electrode, there develops the problem that the threshold voltage to turn on the PMOSFET becomes higher as time passes (for example, refer to K. Ichinose, et al., A High Performance 0.12 μm CMOS with Manufacturable 0.18 μm Technology, IEEE, 2001 Symposium on VLSI Technology Digest of Technical Paper). This is due to a degradation phenomenon of transistor performance called NBTI (i.e., Negative Bias Temperature Instability). It is understood that the cause of the performance degradation is the fact that the hydrogen and other materials mixed during the semiconductor manufacturing process steps are eventually dissociated to change the interface state. Furthermore, when the PMOSFET is concerned, the boron (B) of the gate electrode gets into the gate oxide film.

### SUMMARY OF THE INVENTION

When a PMOSFET is used, there also appears another problem of unstable bias temperature so-called PBTI (Positive Bias Temperature Instability) due to the bias temperature being applied, in addition to the NBTI problem. This performance degradation grows to be significant particularly when the gate width is narrow in the case of a fine PMOS transistor.

Under the circumstance described above, the present invention intends to propose a PMOSFET semiconductor device, in which the transistor performance degradation such as NBTI etc. is suppressed, and a manufacturing method of the same.

The semiconductor device of the present invention is a device that includes a P-channel type MOS field effect transistor (PMOSFET), comprising:

a semiconductor substrate;

a gate oxide film positioned on the semiconductor substrate;

a gate electrode positioned on the gate oxide film; and

two P+ source and drain diffusion areas, each of which has a P− offset area, that are formed in an n-well region of the semiconductor substrate; wherein

at least one of the gate electrode, the gate oxide film and the offset areas contains fluorine.

According to this structure, it becomes possible to materialize a PMOSFET semiconductor device, in which the transistor performance degradation such as NBTI etc. is suppressed.

Further, in the semiconductor device of the present invention, it is desirable that at least one of the gate electrode, the gate oxide film and the offset areas contains fluorine as either a single element or boron fluoride.

According to this structure, it becomes possible by including the fluorine into any of the gate electrode, the gate oxide film and the offset areas to materialize a PMOSFET semiconductor device, in which the transistor performance degradation such as NBTI etc. is suppressed.

Further, in the semiconductor device of the present invention, it is moreover desirable that the gate oxide film contains nitrogen.

According to this structure, it becomes possible to suppress dissociation of hydrogen at the interface between the gate oxide film and the gate electrode.

A manufacturing method of a semiconductor device that includes a P-channel type MOS field effect transistor, according to the present invention can comprise:

forming a gate oxide film on a semiconductor substrate; forming a gate electrode on the gate oxide film;

forming P− offset areas in the semiconductor substrate; and

forming P+ source and drain diffusion areas in the semiconductor substrate; and

including fluorine into the gate electrode after any one of forming the gate electrode;

forming the offset areas; and

forming the source and drain diffusion areas.

A manufacturing method of a semiconductor device that includes a P-channel type MOS field effect transistor according to the present invention can comprise:

forming a gate oxide film on a semiconductor substrate;

forming a gate electrode on the gate oxide film;

forming P− offset areas in the semiconductor substrate; and

forming P+ source and drain diffusion areas in the semiconductor substrate; and

including fluorine into the gate oxide film after any one of:

forming the gate oxide film;

forming the gate electrode;

forming the offset areas; and

forming the source and drain diffusion areas.

A manufacturing method of a semiconductor device that includes a P-channel type MOS transistor according to the present invention can comprise:

forming a gate oxide film on a semiconductor substrate;

forming a gate electrode on the gate oxide film;

forming P− offset areas in the semiconductor substrate; and

a process step of forming P+ source and drain diffusion areas in the semiconductor substrate; and

including fluorine into the offset areas after forming the offset areas.

According to this structure, it becomes possible by including fluorine into any of the gate electrode, the gate oxide film and the offset areas to materialize a PMOSFET semiconductor device, in which the transistor performance degradation such as NBTI etc. is suppressed.

Further, in the semiconductor device of the present invention, it is desirable that at least one of the gate electrode, the gate oxide film and the offset areas contains fluorine as either a single element or boron fluoride.

According to this structure, it becomes possible by including fluorine into at least one of the gate electrode, the gate oxide film and the offset areas to materialize a PMOSFET semiconductor device, in which the transistor performance degradation such as NBTI etc. is suppressed.

Further, in the manufacturing method of the semiconductor device of the present invention, in order to include nitrogen in the gate oxide film, nitrogen can be included in the gate oxide film either during or after a process step of forming the gate oxide film.

According to this structure, it becomes possible to suppress dissociation of hydrogen at the interface between the gate oxide film and the gate electrode.

### BRIEF DESCRIPTION OF THE DRAWINGS

FIG. 1 graphically shows a P-channel MOSFET in section according to an embodiment of the present invention.

FIG. 2 graphically shows a MOSFET manufacturing process in section according to this embodiment.

FIG. 3 graphically shows a MOSFET manufacturing process in section, which follows FIG. 2, according to this embodiment.

FIG. 4 graphically shows a MOSFET manufacturing process in section, which follows FIG. 3, according to this embodiment.

FIG. 5 graphically shows a MOSFET manufacturing process in section, which follows FIG. 4, according to this embodiment.

FIG. 6 graphically shows a MOSFET manufacturing process in section, which follows FIG. 5, according to this embodiment.

FIG. 7 graphically describes a process step of including fluorine into a gate electrode.

FIG. 8 graphically describes a process step of including fluorine into a gate oxide film.

FIG. 9 graphically describes a process step of including fluorine into a plurality of LDD areas.

FIG. 10 graphically describes a process step of including fluorine into a plurality of source and drain diffusion areas.

FIG. 11 graphically shows a part of a P-channel MOSFET in section to indicate the areas R1 and R2.

FIG. 12 graphically shows density of boron fluoride and boron in relation to depth of a semiconductor substrate.

FIG. 13 graphically shows change values of threshold voltage according to a simulation.

### DESCRIPTION OF THE PREFERRED EMBODIMENTS

This section describes a preferred embodiment of the present invention while referring to the drawings.

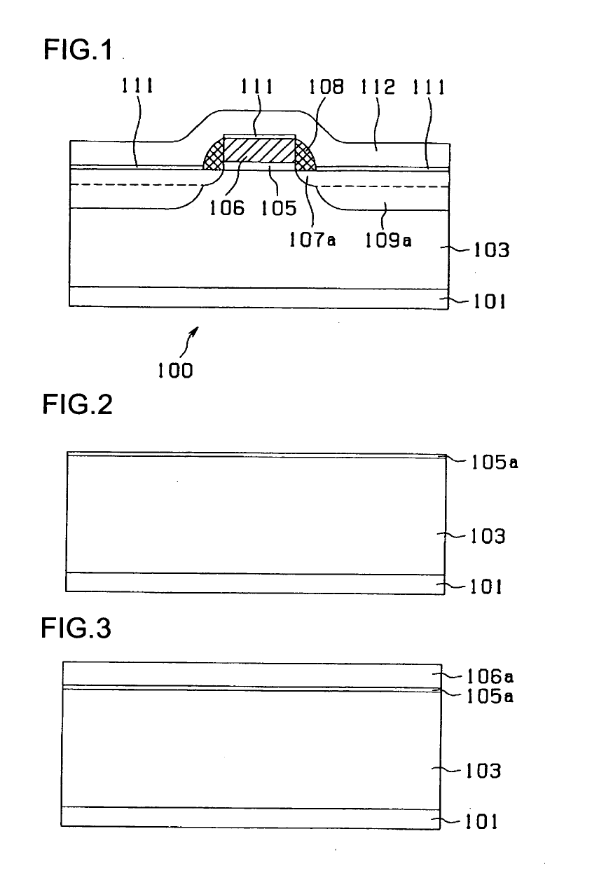

At first, a structure of a P-channel type MOS field effect transistor, i.e., PMOSFET, of the preferred embodiment of the present invention is described while referring to FIG. 1, which shows the P-channel MOSFET in section.

FIG. 1 graphically shows a semiconductor device 100, which is a PMOSFET having offset areas. 101 is a P-type silicon semiconductor substrate 101, and 103 is an n-well region placed on the P-type silicon semiconductor substrate 101. 105 is a gate oxide film, and 106 is a gate electrode placed on the gate oxide film 105. 108 is a plurality of side wall regions. 107a is a plurality of P− offset areas (“P−” means a small amount of acceptors), and 109a is a plurality of P+ source and drain diffusion areas (“P+” means a great amount of acceptors). 111 is a plurality of titanium-silicide layers, and 112 is a protecting film.

In the PMOSFET of this embodiment, at least one of the gate electrode 106, the gate oxide film 105 and the offset areas 107a contains fluorine (F), which suppresses dissociation of hydrogen (H) of Si—H (silicon-hydrogen) combination in the gate electrode 106, the gate oxide film 105 or the offset areas 107a to make improvements on the NBTI performance, etc.

The fluorine becomes included into at least one of the gate electrode 106, the gate oxide film 105 and the offset areas 107a as either a single element of fluorine (F) or boron fluoride (BF₂) through the manufacturing process step(s) described herein.

At first, by using FIG. 2 to FIG. 6, a manufacturing method of the PMOSFET 100 will be described. Then, a method of including fluorine (F) into the gate electrode 106, the gate oxide film 105 or the offset areas 107a will be explained.

FIG. 2 to FIG. 6 graphically show a manufacturing method of the PMOSFET 100 related to the preferred embodiment of the present invention, in which titanium-silicide is used for the interconnect area.

At first, an oxide film 102 (not illustrated in the drawing) is formed on a surface of the P-type silicon semiconductor substrate 101 by thermal oxidation treatment. The oxide film 102 is required for preventing erroneous distribution of ions to be implanted in the following ion implantation process step. Next, phosphorus (P) ions are implanted by ion implantation. Thereafter, by thermal diffusion in nitrogen environment, the n-well region 103 for forming the PMOSFET is formed.

Next, by etching the oxide film 102, another oxide film 104 (not illustrated in the drawing) is formed by thermal oxidation treatment. This oxide film is required for preventing erroneous distribution of ions to be implanted in the ion implantation process step.

Subsequently, ion implantation of boron fluoride (BF₂) for controlling the threshold voltage of the MOS device is carried out. Then, after etching the oxide film 104, a gate oxide film layer 105a that eventually becomes the gate oxide film 105 by thermal treatment is formed (FIG. 2).

In order to make use of the phenomenon that nitrogen has an effect of suppressing dissociation of hydrogen (H), nitrogen is included into the gate oxide film layer 105a. A treatment to include nitrogen into the gate oxide film layer 105a is carried out at the time of or after forming the gate oxide film layer 105a shown in FIG. 2. By including nitrogen into the gate oxide film layer 105a, becomes included into an internal section of the gate oxide film 105 or forms a nitric oxide film onto a surface of the gate oxide film 105, i.e., at the interface between the gate oxide film 105 and the gate electrode 106 to have much fluorine (F) there.

As a method to include nitrogen in the gate oxide film layer 105a, any of the following methods can be applied:

(1) Oxidizing and nitrifying are carried out with nitric gas included in the water vapor environment when the gate oxide film layer 105a shown in FIG. 2 is formed.

(2) After the gate oxide film layer 105a, which becomes the gate oxide film shown in FIG. 2, is formed; a process of RTA (Rapid Thermal Anneal), i.e., a nitrifying process, is carried out with nitrogen gas included.

(3) After the gate oxide film layer 105a, which becomes the gate oxide film shown in FIG. 1, is formed; nitrogen ions are implanted.

In the method of item (2), where a high-temperature thermal treatment, i.e., a nitrifying process, is carried out with nitrogen gas included after the gate oxide film layer 105a is formed; the amount of included nitrogen in the direction of the depth of the gate oxide film layer 105a varies according to the thermal treatment conditions.

Likewise, in the method of item (3), where nitrogen ions are implanted after the gate oxide film layer 105a is formed; the amount of included nitrogen in the direction of the depth of the gate oxide film layer 105a varies according to the accelerating energy conditions.

As described above, dissociation of hydrogen (H) of Si—H (silicon-hydrogen) combination is suppressed by including nitrogen into the gate oxide film 105.

Next, phosphorus (P) doped silicon is deposited by CVD method to form a gate electrode layer 106a, which eventually becomes the gate electrode 106 (FIG. 3).

Subsequently, the gate electrode 106 is formed by ordinary photolithography etching process.

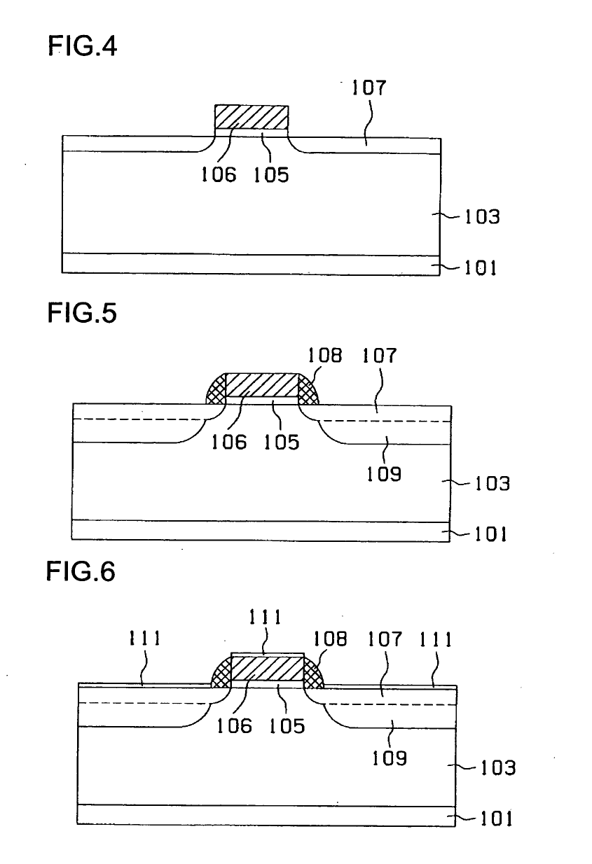

Next, a plurality of P− type LDD (Lightly Doped Drain) areas 107 are formed by boron (B) ion implantation process (FIG. 4).

Subsequently, a plurality of side wall regions 108 are formed by CVD and anisotropic dry-etching. To form the side wall regions 108, silicon oxide (SiO₂) is deposited at first on the entire surface by CVD, and then anisotropic dry-etching is done to form the side wall regions 108. Eventually the P− offset areas 107a are formed right under the side wall regions 108.

Next, a plurality of P+ source and drain areas 109 are formed by boron (B) ion implantation process (FIG. 5).

Then, a film of high melting point titanium is formed by sputtering. Subsequently, a plurality of titanium-silicide layers 111 are formed by thermal treatment to react the titanium with the front-end poly-silicon. Eventually, the titanium placed on the oxide film is removed by titanium-selective etching (FIG. 6).

Next, impurities are activated by annealing to eventually form the PMOSFET 100. Finally, the silicon nitride (Si₃N₄) film 112 as a protecting film or an interlayer insulating film is deposited on the entire surface (FIG. 1). An alternative method, which can be applied for forming the film 112, is to form a silicon oxide (SiO₂) layer on the PMOSFET 100 and then form a silicon nitride film on it as a deposit.

Subsequently, the following sections describe methods of including fluorine (F) into the gate electrode 106, the gate oxide film 105, and the offset areas 107a in the manufacturing method explained above:

(1) A Method of Including Fluorine (F) into the Gate Electrode:

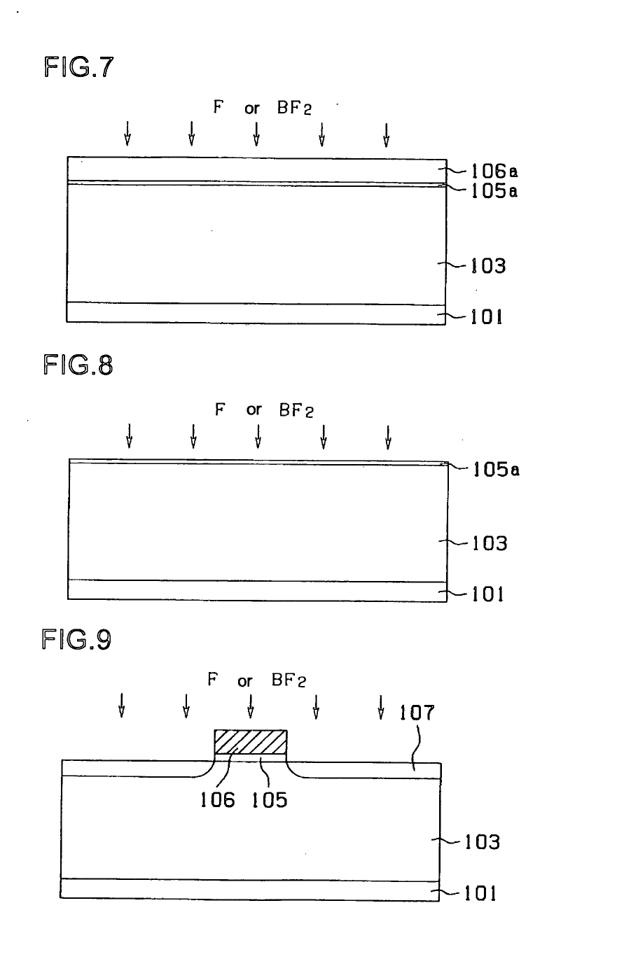

After depositing the phosphorus (P) doped silicon 106a, which eventually becomes the gate electrode, onto the oxide film layer 106a, which finally becomes the gate oxide film, by applying CVD (FIG. 3); ion implantation with a single element of fluorine (F) or boron fluoride (BF₂) is done so as to include fluorine (F) into the gate electrode as shown in FIG. 7. Then, carrying out ordinary photolithography etching process thereafter makes it possible that only the gate electrode 106 contains fluorine (F). On this occasion, by controlling the accelerating energy of ion implantation, it becomes possible to include fluorine (F) only into the gate electrode 106 or to include fluorine (F) not only into the gate electrode 106 but also into the interface between the gate electrode 106 and the gate oxide film 105, or down to the interface between the gate oxide film layer 105 and the n-well region 103 as well.

(2) A Method of Including Fluorine (F) into the Gate Oxide Film:

After forming the gate oxide film layer 105a by thermal treatment (FIG. 2), ion implantation with a single element of fluorine (F) or boron fluoride (BF₂) is done so as to include fluorine (F) into the gate oxide film as FIG. 8 shows. On this occasion, by controlling the accelerating energy of ion implantation, it becomes possible to include fluorine (F) only into the gate oxide film layer 105a. Particularly, by controlling the accelerating energy of ion implantation, it becomes possible to include fluorine (F) principally onto the surface of the gate oxide film layer 105a or mainly onto the interface between the gate oxide film layer 105a and the n-well region 103. Namely, when the gate oxide film 105a contains fluorine (F), the implantation is controlled so that the fluorine (F) is richly included in at least either the interface between the gate electrode 106 and the gate oxide film layer 105a or the interface between the n-well region 103 of the semiconductor substrate and the gate oxide film layer 105a.

(3) A Method of Including Fluorine (F) into the Offset Areas 107a:

After forming the offset areas (FIG. 4), ion implantation with a single element of fluorine (F) or boron fluoride (BF₂) is done so as to include fluorine (F) into the LDD areas 107 as FIG. 9 shows.

When ion implantation with fluorine (F) or boron fluoride (BF₂) is implemented to include fluorine (F) into the offset areas 107a, fluorine (F) gets implanted into the gate electrode 106 as well, and also into the gate oxide film 105, depending on the accelerating energy of ion implantation. That is to say; the accelerating energy of ion implantation determines whether fluorine (F) gets implanted only into the internal section of the gate electrode 106, or down to the interface between the gate electrode 106 and the gate oxide film 105, or down to the internal section of the gate oxide film 105, or even down to the interface between the gate oxide film 105 and the n-well region 103.

In this embodiment, fluorine (F) gets included in the gate electrode 106 and the gate oxide film 105 so that dissociation of hydrogen (H) of Si—H (silicon-hydrogen) combination is suppressed by the fluorine (F) included in the gate electrode 106 and the gate oxide film 105, and this effect is favorable from the viewpoint on the transistor performance degradation such as NBTI etc.

Though this embodiment describes a case of implementing ion implantation with fluorine (F) or boron fluoride (BF₂) after ion implantation with boron (B) to form the LDD areas 107, the ion implantation with boron (B) can be done even after the ion implantation with fluorine (F) or boron fluoride (BF₂).

(4) A Method of Including Fluorine (F) into the Source and Drain Diffusion Areas 109:

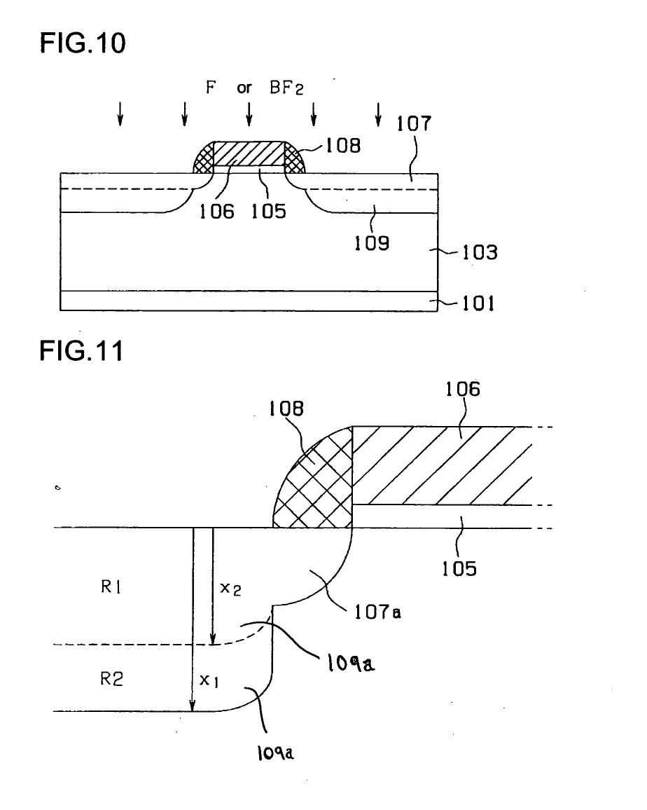

After forming the source and drain diffusion areas 109a (FIG. 1), ion implantation with a single element of fluorine (F) or boron fluoride (BF₂) is done so as to include fluorine (F) into the gate electrode 106, the gate oxide film 105, and the source and drain diffusion areas 109a, as FIG. 10 shows. In this ion implantation process, neither fluorine (F) nor boron fluoride (BF₂) is implanted into the offset areas 107a positioned right under the side walls 108 because there exist the side walls 108.

When ion implantation with fluorine (F) or boron fluoride (BF₂) is implemented to include fluorine (F) into the source and drain diffusion areas 109a, fluorine (F) gets implanted into the gate electrode 106 as well, and furthermore into the gate oxide film 105 as well, depending on the accelerating energy of ion implantation. However, fluorine (F) gets included in the gate electrode 106 and the gate oxide film 105 so that dissociation of hydrogen (H) of Si—H (silicon-hydrogen) combination is suppressed by the fluorine (F) included in the gate electrode 106 and the gate oxide film 105, and this effect is favorable from the viewpoint on the transistor performance degradation such as NBTI etc.

Incidentally, when ion implantation into the source and drain diffusion areas 109a with boron fluoride (BF₂) is implemented to make improvements on the transistor performance degradation, crystal defects may easily be caused in the source and drain diffusion areas 109a so that the current while the PMOSFET being turned off, i.e., the leak current, is likely to get increased.

Therefore, when ion implantation into the source and drain diffusion areas 109a with boron fluoride (BF₂) is implemented to make improvements on the NBTI performance, etc.; the accelerating energy of ion implantation with boron fluoride (BF₂) is controlled so that the distance from the principal surface to a depth, down to which ion implantation with boron fluoride (BF₂) is implemented, is shorter than the distance from the principal surface to another depth, down to which ion implantation with boron (B) is implemented, in relation to the distance from the principal surface to each corresponding depth.

Namely, when ion implantation with boron (B) and boron fluoride (BF₂) is implemented in the process step of forming the source and drain diffusion areas 109a, the accelerating energy of ion implantation with boron fluoride (BF₂) is set to be smaller than that with boron (B).

On this occasion, ion implantation with boron fluoride (BF₂) can be done, not only after ion implantation with boron (B) to form the source and drain diffusion areas 109a, but even before it.

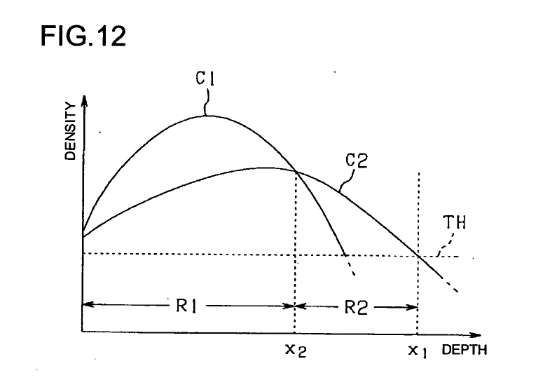

FIG. 11 illustrates a P-channel type MOSFET in section to graphically show an area R1 where boron fluoride (BF₂) density is higher than boron (B) density, as well as another area R2 where boron (B) density is higher than phosphorus (P) density, in a semiconductor substrate when ion implanting operations with boron fluoride (BF₂) and boron (B) are individually carried out. FIG. 12 graphically explains density of the boron fluoride (BF₂) and boron (B) in relation to the depth from the principal surface of the semiconductor substrate when ion implanting operations with boron fluoride (BF₂) and boron (B) are individually carried out in a semiconductor substrate.

In FIG. 12; C1, C2 and TH show a density curve of boron fluoride (BF₂), a density curve of boron (B), and phosphorus (P) density in the n-well region 103, respectively. Consequently, when ion implanting operations with boron fluoride (BF₂) and boron (B) are individually carried out under the conditions described above, the boron fluoride (BF₂) density is higher than the boron (B) density in the area from the principal surface of the semiconductor substrate to the depth X2, meanwhile boron (B) density is higher than the phosphorus (P) density in the area from the depth X2 to the depth X1, each of which is measured out of the principal surface of the semiconductor substrate, as shown in FIG. 11 and FIG. 12

As shown in FIG. 12, the boron fluoride (BF₂) density and the boron (B) density are provided with distribution. Therefore, in the source and drain diffusion areas 109a, the area mainly including boron fluoride (BF₂) (i.e., the area where the boron fluoride (BF₂) density is higher than the boron (B) density) exists outside the area mainly including boron (B) (i.e., the area where the boron (B) density is higher than the boron fluoride (BF₂) density).

As a result, even though any crystal defects are caused in the semiconductor substrate by ion implantation with boron fluoride (BF₂), the area having such crystal defects is positioned away from the PN-junction plane between the source and drain diffusion areas 109a, containing the boron (B) ion-implanted to form the source and drain diffusion areas 109a, and the n-well region 103 so that any leak current is unlikely to happen. That is to say; since the area having such crystal defects is enclosed with the PN-junction plane, improvements are eventually made on the performance degradation such as NBTI, etc., and furthermore the leak current can be reduced.

Incidentally, after forming the side walls 108, it is possible to lightly implement ion implantation with boron fluoride (BF₂) at first and then deeply implement ion implantation with boron (B); or to deeply implement ion implantation with boron (B) at first and then lightly implement ion implantation with boron fluoride (BF₂).

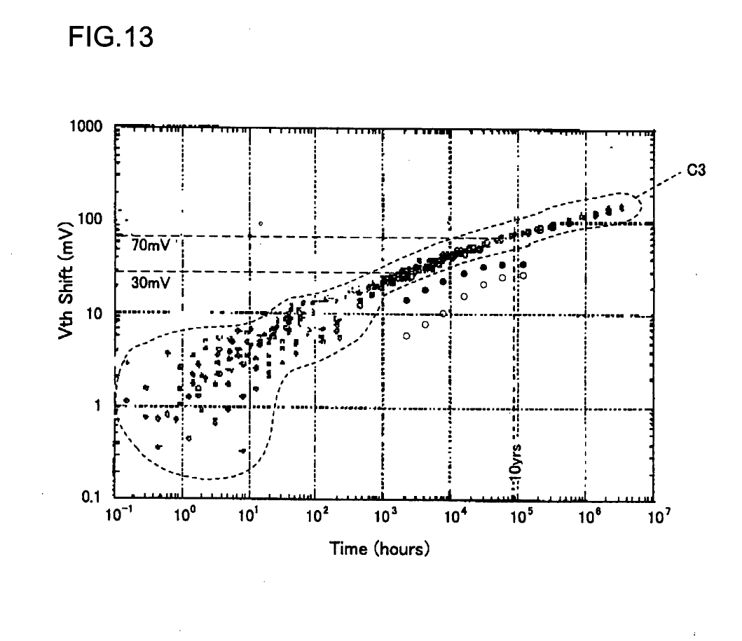

FIG. 13 graphically shows the change values of threshold voltage in relation to passage of time in a simulation by accelerated test at 125 degrees Celsius.

FIG. 13 shows the simulation result with a PMOSFET provided with; 10 μm gate width, 0.18 μm gate length, and 1.8V operation voltage.

In FIG. 13, the vertical axis indicates the change in threshold voltage to turn on the PMOSFET (unit in mV); meanwhile the horizontal axis indicates the passage of time (unit in hours). In FIG. 13, the points surrounded by the dotted line C3 represent the change values of threshold voltage in relation to the passage of time when conventional PMOSFET units are concerned. Meanwhile, the black circles (●) and white circles (∘) represent the change values of threshold voltage in relation to the passage of time when PMOSFET units related to this preferred embodiment are concerned. Consequently, the change values of the conventional units reach 70 mV in around 10 years, and on the other hand, those of the units related to this preferred embodiment are 30 mV in around 10 years. Therefore, it is understood that performance degradation of NBTI can be suppressed by applying this embodiment.

Furthermore, if ion implantation with boron fluoride (BF₂) is shallowly implemented after forming the side walls 108 and then ion implantation with boron (B) is subsequently implemented deeply, the leak current can be reduced.

Therefore, according to this embodiment, performance degradation of NBTI can be suppressed in the PMOSFET.

The present invention is not restricted only to the embodiment described above, but various other changes and modifications can also be made.

What is claimed is:

1. A semiconductor device that includes a P-channel type MOS field effect transistor (PMOSFET), comprising:
a semiconductor substrate;
a gate oxide film positioned on the semiconductor substrate;
a gate electrode positioned on the gate oxide film; and
two P+ source and drain diffusion areas, each of which has a P− offset area, that are formed in an n-well region inside the semiconductor substrate; wherein
at least one of the gate electrode, the gate oxide film and the offset areas contains fluorine.

2. The semiconductor device according to claim 1, wherein at least one of the gate electrode, the gate oxide film and the offset areas contains the fluorine as either a single element or boron fluoride.

3. The semiconductor device according to either claim 1 or claim 2, further characterized that the gate oxide film contains nitrogen.

4. A manufacturing method of a semiconductor device that includes a P-channel type MOS field effect transistor, comprising:
forming a gate oxide film on a semiconductor substrate;
forming a gate electrode on the gate oxide film;
forming P− offset areas in the semiconductor substrate;
forming P+ source and drain diffusion areas in the semiconductor substrate; and
including fluorine in the gate electrode, wherein said including is implemented after any one of:
forming the gate electrode;
forming the offset areas; and
forming the source and drain diffusion areas.

5. The manufacturing method of a semiconductor device according to claim 4 characterized that the gate electrode contains the fluorine as either a single element or boron fluoride.

6. The manufacturing method of a semiconductor device according to either claim 4 or claim 5, further comprising including nitrogen into the gate oxide film either during or after a process step of forming the gate oxide film.

7. A manufacturing method of a semiconductor device that includes a P-channel type MOS field effect transistor, comprising:
forming a gate oxide film on a semiconductor substrate;
forming a gate electrode on the gate oxide film;
forming P− offset areas in the semiconductor substrate;
forming P+ source and drain diffusion areas in the semiconductor substrate; and
including fluorine into the gate oxide film after any one of:
forming the gate oxide film;
forming the gate electrode;
forming the offset areas; and
forming the source and drain diffusion areas.

8. The manufacturing method of a semiconductor device according to claim 7 characterized that the gate oxide film contains the fluorine as either a single element or boron fluoride.

9. The manufacturing method of a semiconductor device according to either claim 7 or claim 8, further comprising including nitrogen into the gate oxide film either during or after a process step of forming the gate oxide film.

10. A manufacturing method of a semiconductor device that includes a P-channel type MOS transistor, comprising:
forming a gate oxide film on a semiconductor substrate;
forming a gate electrode on the gate oxide film;
forming P− offset areas in the semiconductor substrate;
forming P+ source and drain diffusion areas in the semiconductor substrate; and
including fluorine into the offset areas after forming the offset areas.

11. The manufacturing method of a semiconductor device according to claim 10 characterized by a feature that the above offset areas contain the fluorine as either a single element or boron fluoride.

12. The manufacturing method of a semiconductor device according to either claim 10 or claim 11, further including nitrogen into the gate oxide film either during or after a process step of forming the gate oxide film.

13. The method according to claim 4, wherein the fluorine is included in the gate electrode by ion implantation.

14. The method of claim 13, wherein the accelerating energy of the ion implantation is controlled.

15. The method according to claim 7, wherein the fluorine is included in the gate oxide film by ion implantation.

16. The method of claim 15, wherein the accelerating energy of the ion implantation is controlled.

17. The method according to claim 10, wherein the fluorine is included in the offset areas by ion implantation.

18. The method of claim 17, wherein the accelerating energy of the ion implantation is controlled.

19. A manufacturing method of a semiconductor device that includes a P-channel type MOS field effect transistor, comprising:
forming a gate oxide film on a semiconductor substrate;
forming a gate electrode on the gate oxide film;
forming P− offset areas in the semiconductor substrate;
forming P+ source and drain diffusion areas in the semiconductor substrate; and
including fluorine in the source and drain diffusion areas, wherein said including is implemented after forming the source and drain diffusion areas.

20. The method according to claim 19, wherein the fluorine is included in the source and drain diffusion areas by ion implantation.

21. The method of claim 20, wherein the accelerating energy of the ion implantation is controlled.

22. The method of claim 20, wherein the ion implantation is done using boron fluoride, and accelerating energy of ion implantation with the boron fluoride is controlled so that the distance from a principal surface to a first depth, down to which ion implantation with boron fluoride (BF₂) is implemented is shorter than a distance from the principal surface to a second depth, down to which ion implantation with boron (B) is implemented.

23. The method of claim 20 wherein the ion implantation is done using boron and boron fluoride, and the accelerating energy of ion implantation with boron fluoride is smaller than that with boron.

24. The method of claim 19 wherein ion implantation is prevented in offset areas below side walls.

25. The method of claim 13, wherein ion implantation with boron fluoride is shallowly performed after forming side walls on a side portion of the gate electrode, and ion implantation with boron is deeply performed after performing ion implantation with boron fluoride.
